(19) United States
(12) Patent Application Publication
(10) Pub. No.: US 2026/0066206 A1
(43) Pub. Date: Mar. 5, 2026

(54) DRIVER CIRCUIT FOR HIGH VOLTAGE CONTACTOR

(71) Applicant: Allegro MicroSystems, LLC, Manchester, NH (US)

(72) Inventors: Kavul Tshiloz, Edinburgh (GB); Narasimhan Trichy, Plano, TX (US); Andrea Foletto, Andorno Micca (IT)

(73) Assignee: Allegro MicroSystems, LLC, Manchester, NH (US)

(21) Appl. No.: 18/822,641

(22) Filed: Sep. 3, 2024

(51) Int. Cl. H01H 47/32; H01H 47/00; H01H 47/36; H03K 17/687

(52) U.S. Cl. CPC H01H 47/32; H01H 47/001; H01H 47/36; H03K 17/687

(57) ABSTRACT

Methods and apparatus for energizing and de-energizing a coil that controls a position of a contactor. In embodiments, a first switching device is coupled between the first end of a coil and a first potential node and a second switching device is coupled between the second end of the coil and a second potential node. A third switching device is coupled across a connection of the coil and the second switching device and a zener diode coupled across the second switching device. A contactor has a position determined by a current level through the coil.

### BACKGROUND

High-voltage (HV) contactors are widely used in various applications. For example, HV contact mechanisms may be used in the junction box of electric vehicles. HV contactors include an electromechanical switching device with a built-in electrical coil to generate an electromagnetic force that mechanically operates to open and close an electric contact. The physical characteristics of the contactor and varying power bridge stage configurations present challenges for gate drivers to drive signals to control the contactors.

### SUMMARY

Example embodiments of the disclosure provide methods and apparatus for a power stage circuit architecture with a low R_{DS(ON)} integrated in a chip or gate driver to energize and de-energize a contactor using low-side and high-side MOSFETs. The power circuit has an active synchronous recirculation mode achieved by an internal low-side MOSFET. In embodiments, a power circuit provides a low R_{DS(ON)} for automotive applications that require contactors to be disabled quickly for minimizing delay in the systems. In embodiments, an example power stage bridge configuration includes a Zener diode that clamps relatively quickly to decay contactor current by creating a relatively large opposing voltage across the contactor coil to rapidly turn-off the contactor when the contactor is commanded to open.

In one aspect, a device comprises: a first switching device configured for coupling between a first end of a coil and a first potential node; a second switching device configured for coupling between a second end of the coil and a second potential node; a zener diode coupled across the second switching device; and a third switching device coupled to the first and second switching devices, wherein the first, second, and third switching devices and the zener diode are configured to control current to the coil in a plurality of modes for controlling a position of a mechanically biased contactor to selectively electrically connect terminals.

The device can further include one or more of the following features: the first switching device comprises a high side device and the second switching device comprises a low side device, the first, second, and third switching devices comprise FET devices, the device is configured to make a first series circuit path though the first switching device, the coil, and the second switching device, the device is configured to make a second series circuit path though the first switching device, the coil, and the zener diode, the device is configured to make a third series circuit path though the first switching device and the third switching device, the device is configured to make a first circuit loop with the second switching device and the zener diode, the device is configured to make a second circuit loop with the coil, the third switching device and the second switching device, the plurality of modes include drive, recirculate, and drop out, drive mode is configured to move the contactor to connect the terminals, the recirculate mode is configured to maintain the contactor in position to connect the terminals, the drop out mode is configured to enable the zener diode to rapidly de-energize the coil current for disconnecting the terminals, the device is configured so that the coil is not connected to the first or second potential nodes, and/or the first switching device is configured to operate in pulse width modulation mode.

In another aspect, method comprises: coupling, in a gate driver device, a first switching device between a first terminal for a first end of a coil and a first potential node; coupling a second switching device between a second terminal for a second end of the coil and a second potential node; coupling a zener diode across the second switching device; and coupling a third switching device to the first and second switching devices, wherein the first, second, and third switching devices and the zener diode are configured to control current to the coil in a plurality of modes for controlling a position of a mechanically biased contactor to selectively electrically connect terminals.

The method can further include one or more of the following features: the first switching device comprises a high side device and the second switching device comprises a low side device, the first, second, and third switching devices comprise FET devices, the device is configured to make a first series circuit path though the first switching device, the coil, and the second switching device, the device is configured to make a second series circuit path though the first switching device, the coil, and the zener diode, the device is configured to make a third series circuit path though the first switching device and the third switching device, the device is configured to make a first circuit loop with the second switching device and the zener diode, the device is configured to make a second circuit loop with the coil, the third switching device and the second switching device, the plurality of modes include drive, recirculate, and drop out, drive mode is configured to move the contactor to connect the terminals, the recirculate mode is configured to maintain the contactor in position to connect the terminals, the drop out mode is configured to enable the zener diode to rapidly de-energize the coil current for disconnecting the terminals, the device is configured so that the coil is not connected to the first or second potential nodes, and/or the first switching device is configured to operate in pulse width modulation mode.

### BRIEF DESCRIPTION OF THE DRAWINGS

The foregoing features of this disclosure, as well as the disclosure itself, may be more fully understood from the following description of the drawings in which:

FIG. 1 is a schematic representation of example coil driver power circuit coupled to a contactor module having a coil for controlling the position of a contact;

FIG. 2A is a waveform diagram showing energization of the coil of FIG. 1 and FIG. 2B shows de-energization of the coil of FIG. 1; and

FIG. 3 is a circuit diagram of an example driver circuit for controlling a coil in a contactor.

### DETAILED DESCRIPTION

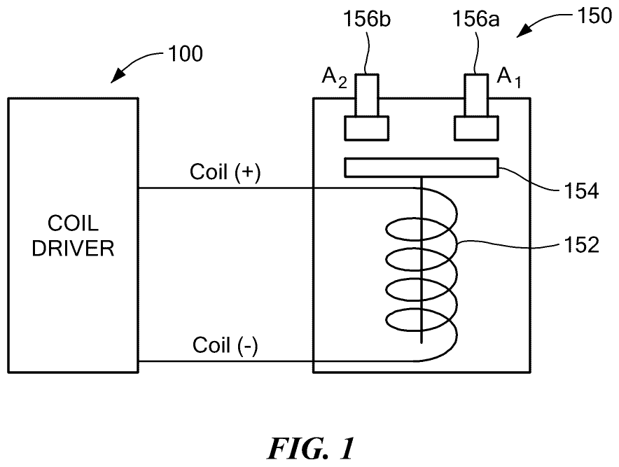

FIG. 1 shows an example coil driver circuit 100 coupled to a contactor module 150 having a coil 152 for controlling the position of a contactor 154. The coil driver circuit 100 generates signals to respective positive (+) and negative (−) ends of the coil 152 to move the contactor 154 and close an electrical connection between first and second terminals 156a,b. In embodiments, the coil driver 100 generates excitation signals to the coil 152 during an energization phase to quickly move the contact 154 to make an electrical connection between the terminals 156a,b. After the contact 154 closes the electrical connection, the coil driver 100 generates a hold current during a hold phase to maintain the electrical connection. It will be readily appreciated that the hold current level is less than the initial current level to move the contact 154.

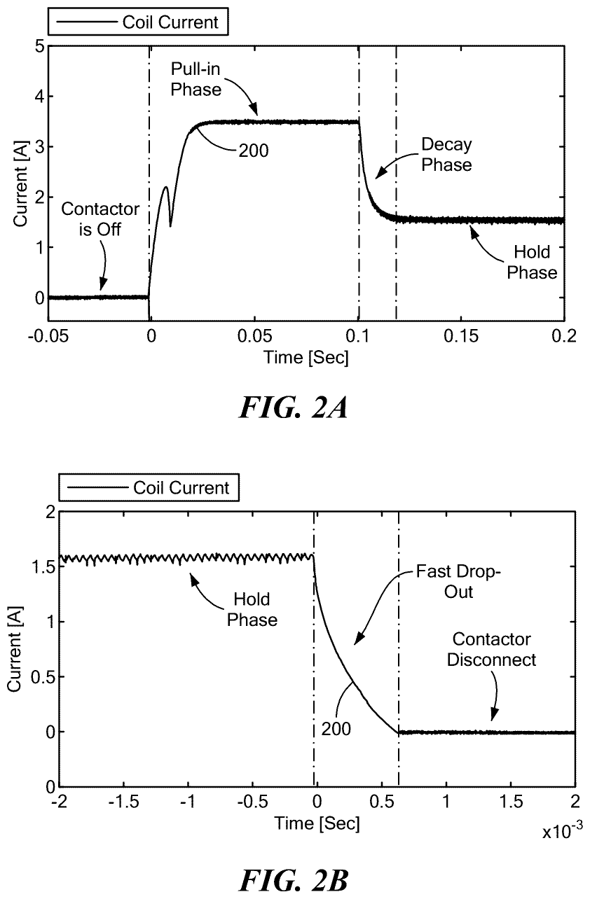

FIG. 2A shows an example coil current 200 waveform for an example energization phase to move the contact 154 (FIG. 1) to make an electrical connection to the terminals 156a,b. In the illustrated embodiment, when the contactor is in the OFF position, the coil current 200 is zero or less than some threshold value. During the energization to move the contactor during a pull-in phase, the coil current 200 ramps up to a first level for the pull-in phase, which is about 3.5 A in the illustrated embodiment. This current overcomes the bias, such as from a spring, of the contactor to an open position. In the illustrated embodiment, the pull-in time to close the contact is about 100 ms. After contactor close is achieved, the coil current decays in a decay phase until reaching a steady state hold current level, e.g., 1.5 A, in a hold phase during which the contactor position is maintained to keep the terminals electrically connected.

FIG. 2B shows the hold phase current level 200 rapidly decrease to 0 A as the contact turns off which can be referred to as the de-energizing time. This rapid decrease in current level can be referred to as fast drop out phase spanning about 0.5 ms in the illustrated embodiment. The fast drop out spans a time for the coil current 200 to decrease from the hold phase current, e.g., 1.5 A, that maintains the contact in the closed position to zero current when the contactor is completely disconnected. In embodiments, a Zener diode in the coil driver circuit allows a fast decay of the current to zero in less than 1 ms, for example, as described below.

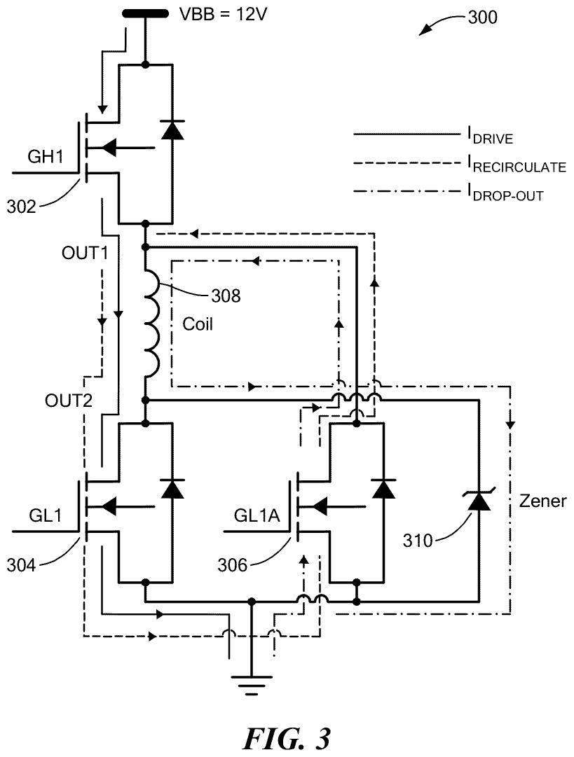

FIG. 3 shows an example circuit implementation of a coil driver circuit 300 to provide rapid de-energization of a contactor. First and second transistors 302, 304 are coupled in a half bridge configuration. In the illustrated embodiment, the first transistor 302 can be referred to as a high side transistor and the second transistor 304 can be referred to as a first low side transistor.

A third transistor 306 can be referred to as a second low side transistor coupled across the first low side transistor 304 and a coil 308, which is coupled between the high and low side transistors 302, 304. In the illustrated example embodiment, a zener diode 310 is coupled across the first low side transistor 304. In example embodiments, the first transistor 302 and the first low side transistor 304 comprise low R_{DS(ON)} power devices. In an example embodiment of low R_{DS(ON)}, High-side MOSFET 302=60 mΩ, Low-side MOSFET 304=30 mΩ, and Low-side MOSFET 306=60 mΩ.

It is understood that R_{DS(ON)} refers to MOSFET drain-to-source (DS) on-state resistance. When the FET is in cutoff, the resistance between source and drain is extremely high so that zero current is assumed. When gate-to-source voltage (V_{GS}) exceeds the threshold voltage (V_{TH}), the FET is in the on state in which the drain and source are connected by a channel with resistance equal to R_{DS(on)}.

A first gate drive signal GH1 controls the conductive state of the first device 302, a second gate drive signal GL1 controls the conductive state of the second device 304, and a third gate drive signal GL1A controls the conductive state of the third device 306.

The illustrative circuit 300 of FIG. 3 includes a low R_{DS(ON)} power stage bridge architecture integrated inside a chip or gate driver to energize and de-energize a contactor using the low-side and high-side MOSFETs 302, 304 with an active synchronous recirculation achieved by the second low-side MOSFET (third device) 306. In embodiments, a gate driver IC package is configured for connection to ends of the coil 308, which is integrated in a contactor device, as shown in FIG. 1. The internal Zener diode 310 can very quickly decay the contactor current in the fast drop out phase (FIG. 2B) by creating a large opposing voltage across the contactor coil 308 to rapidly turn-off the contactor when the contactor is commanded to open. In some embodiments, contactors in automotive applications must be disabled quickly to minimize delay in various systems.

In embodiments, the coil 308 is disconnected from the voltage supply and from ground. The switching devices 302, 304 can comprise low R_{DSON} devices for low power dissipation and high efficiency operation. The circuit to control the contactor position provides rapid turn-off and contactor disconnect. In embodiments, relatively low voltage rated integrated MOSFETs can be used. In one particular embodiment, low voltage MOSFET ratings comprise high-side MOSFET 302=45V, Low-side MOSFET 304=45V, and second Low-side MOSFET 306=45V.

Example circuit implementations enable a complete disconnect of the coil 303 from both supply VBB and ground which permits the low-side and high-side MOSFETs 302, 304 to be driven independently and operate in close loop current regulation mode as illustrated in Table 1 below, which shows the state of each switching element in the drive (pull in phase), recirculate (hold phase) and drop out (phase) modes of operation. As shown and described below, in half-bridge synchronous recirculation, the current in contactor coil is regulated in PWM mode through GH1 302 and GL1A MOSFETs 306 when GL1 304 is in the turn-on state.

TABLE 1
Power Stage Configuration

| Mode | EN = 1 | PWMIN1 | GH1 | GL1 | GL1A |
|---|---|---|---|---|---|
| Drive | 1 | 1 | 1 | 1 | 0 |
| Recirculate | 1 | 0 | 0 | 1 | 1 |
| Drop out | 0 | X | 0 | 0 | 1 |

During current regulation in drive mode, the low-side MOSFET 304 is turned-on (EN=1) and the high-side MOSFET 302 is enabled and operates in PWM (pulse width modulation) mode (PWMIN1=1) to regulate the current to the coil. In recirculate mode, when the high-side MOSFET 302 is turned-off (GH1=0), still in PWM mode, the current can recirculate in synchronous recirculation mode as shown with the first low side MOSFET 304 and second low side MOSFET 306 on. The coil current can be monitored on the low-side and high-side MOSFETs for accurate current control during current regulation and/or diagnostic purposes. In example embodiments, the coil current is monitored by measuring the voltage drop across the low-side MOSFET 304 during driving and recirculation for closed loop current control. The voltage drop across the low-side MOSFET 304 will be the product of the coil current and the low R_{DS(ON)} resistance of the low-side MOSFET.

In drop out mode, the Zener diode 310 recirculates the current at the Zener voltage level (e.g., in the order of 40V) for fast de-energization or fast drop-out of the contactor when the first low-side MOSFET 304 (GL1=0) is commanded to turn-off and the second low-side MOSFET 306 (GL1A=1) is on.

Various embodiments of the concepts systems and techniques are described herein with reference to the related drawings. Alternative embodiments can be devised without departing from the scope of the described concepts. It is noted that various connections and positional relationships (e.g., over, below, adjacent, etc.) may be set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to element or structure “A” over element or structure “B” include situations in which one or more intermediate elements or structures (e.g., element “C”) is between element “A” and element “B” regardless of whether the characteristics and functionalities of element “A” and element “B” are substantially changed by the intermediate element(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a method, article, or apparatus that comprises a list of elements is not necessarily limited to only those elements but can include other elements not expressly listed or inherent to such method, article, or apparatus.

Additionally, the terms “one or more” and “one or more” are understood to include any integer number greater than or equal to one, i.e. one, two, three, four, etc. The terms “a plurality” are understood to include any integer number greater than or equal to two, i.e., two, three, four, five, etc. The term “connection” can include an indirect “connection” and a direct “connection”.

References in the specification to “one embodiment,” “an embodiment,” “an example embodiment,” or variants of such phrases indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection knowledge of one skilled in the art to affect such feature, structure, or characteristic in connection with other embodiments whether or not explicitly described.

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” surface can become a “lower” surface simply by turning the object over. Nevertheless, it is still the same surface and the object remains the same. Also, as used herein, “and/or” means “and” or “or”, as well as “and” and “or.” Moreover, all patent and non-patent literature cited herein is hereby incorporated by references in their entirety.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements.

Having described exemplary embodiments, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A device, comprising:
a first switching device configured for coupling between a first end of a coil and a first potential node;
a second switching device configured for coupling between a second end of the coil and a second potential node;
a zener diode coupled across the second switching device; and
a third switching device coupled to the first and second switching devices, wherein the first, second, and third switching devices and the zener diode are configured to control current to the coil in a plurality of modes for controlling a position of a mechanically biased contactor to selectively electrically connect terminals.

2. The device according to claim 1, wherein the first switching device comprises a high side device and the second switching device comprises a low side device.

3. The device according to claim 1, wherein the first, second, and third switching devices comprise FET devices.

4. The device according to claim 1, wherein the device is configured to make a first series circuit path though the first switching device, the coil, and the second switching device.

5. The device according to claim 4, wherein the device is configured to make a second series circuit path though the first switching device, the coil, and the zener diode.

6. The device according to claim 5, wherein the device is configured to make a third series circuit path though the first switching device and the third switching device.

7. The device according to claim 1, wherein the device is configured to make a first circuit loop with the second switching device and the zener diode.

8. The device according to claim 7, wherein the device is configured to make a second circuit loop with the coil, the third switching device and the second switching device.

9. The device according to claim 1, wherein the plurality of modes include drive, recirculate, and drop out.

10. The device according to claim 9, wherein the drive mode is configured to move the contactor to connect the terminals.

11. The device according to claim 10, wherein the recirculate mode is configured to maintain the contactor in position to connect the terminals.

12. The device according to claim 11, wherein the drop out mode is configured to enable the zener diode to rapidly de-energize the coil current for disconnecting the terminals.

13. The device according to claim 1, wherein the device is configured so that the coil is not connected to the first or second potential nodes.

14. The device according to claim 1, wherein the first switching device is configured to operate in pulse width modulation mode.

15. A method, comprising:
coupling, in a gate driver device, a first switching device between a first terminal for a first end of a coil and a first potential node;
coupling a second switching device between a second terminal for a second end of the coil and a second potential node;
coupling a zener diode across the second switching device; and
coupling a third switching device to the first and second switching devices, wherein the first, second, and third switching devices and the zener diode are configured to control current to the coil in a plurality of modes for controlling a position of a mechanically biased contactor to selectively electrically connect terminals.

16. The method according to claim 15, wherein the first switching device comprises a high side device and the second switching device comprises a low side device.

17. The method according to claim 15, wherein the first, second, and third switching devices comprise FET devices.

18. The method according to claim 15, wherein the gate driver device is configured to make a first series circuit path though the first switching device, the coil, and the second switching device.

19. The method according to claim 18, wherein the gate driver device is configured to make a second series circuit path though the first switching device, the coil, and the zener diode.

20. The method according to claim 19, wherein the gate driver device is configured to make a third series circuit path though the first switching device and the third switching device.

21. The method according to claim 15, wherein the gate driver device is configured to make a first circuit loop with the second switching device and the zener diode.

22. The method according to claim 21, wherein the gate driver device is configured to make a second circuit loop with the coil, the third switching device and the second switching device.

23. The method according to claim 15, wherein the plurality of modes include drive, recirculate, and drop out.

24. The method according to claim 23, wherein drive mode is configured to move the contactor to connect the terminals.

25. The method according to claim 24, wherein the recirculate mode is configured to maintain the contactor in position to connect the terminals.

26. The method according to claim 25, wherein the drop out mode is configured to enable the zener diode to rapidly de-energize the coil current for disconnecting the terminals.

27. The method according to claim 15, wherein the gate driver device is configured so that the coil is not connected to the first or second potential nodes.

28. The method according to claim 15, wherein the first switching device is configured to operate in pulse width modulation mode.
